(19) United States
(12) Patent Application Publication
(10) Pub. No.: US 2022/0293855 A1
(43) Pub. Date: Sep. 15, 2022

(54) STORAGE DEVICE AND STORAGE UNIT

(71) Applicant: SONY SEMICONDUCTOR SOLUTIONS CORPORATION, Kanagawa (JP)

(72) Inventors: Tetsuya MIZUGUCHI, Kanagawa (JP); Katsuhisa ARATANI, Kanagawa (JP)

(73) Assignee: SONY SEMICONDUCTOR SOLUTIONS CORPORATION, Kanagawa (JP)

(21) Appl. No.: 17/641,290

(22) PCT Filed: Aug. 13, 2020
(86) PCT No.: PCT/JP2020/030770

§ 371 Date: Mar. 8, 2022

(30) Foreign Application Priority Data
Sep. 19, 2019 (JP) 2019-170594

(51) Int. Cl. H01L 45/00; H01L 21/8239; G11C 13/00

(52) U.S. Cl. CPC H01L 45/144; H01L 21/8239; H01L 45/143; H01L 45/142; H01L 45/1266; G11C 13/0011

(57) ABSTRACT

A storage device of an embodiment of the present disclosure includes: a first electrode; a second electrode; a storage layer provided between the first electrode and the second electrode and including at least copper, aluminum, zirconium, and tellurium; and a barrier layer provided between the storage layer and the second electrode and including zirconium at a higher concentration than at least the storage layer, the barrier layer having a copper concentration, at an interface with the second electrode, being lower than the storage layer.

### TECHNICAL FIELD

The present disclosure relates to a storage device including a chalcogenide layer between electrodes and a storage unit including the storage device.

### BACKGROUND ART

There have been proposed, as next-generation non-volatile memories, new types of storage devices such as ReRAM (Resistance Random Access Memory (registered trademark) and PCM (Phase Change Memory) (registered trademark) (see, e.g., PTLs 1 and 2).

### CITATION LIST

### Patent Literature

PTL 1: Japanese Unexamined Patent Application Publication No. 2008-135659
PTL 2: Japanese Unexamined Patent Application Publication No. 2009-43873

### SUMMARY OF THE INVENTION

Incidentally, higher density and larger capacity have been demanded in a cross-point type memory cell array.

It is desirable to provide a storage device and a storage unit that have high density and large capacity.

A storage device according to an embodiment of the present disclosure includes: a first electrode; a second electrode; a storage layer provided between the first electrode and the second electrode and including at least copper, aluminum, zirconium, and tellurium; and a barrier layer provided between the storage layer and the second electrode and including zirconium at a higher concentration than at least the storage layer, the barrier layer having a copper concentration, at an interface with the second electrode, being lower than the storage layer.

A storage unit according to an embodiment of the present disclosure includes: one or a plurality of first wiring lines extending in one direction; one or a plurality of second wiring lines extending in another direction and intersecting the first wiring line; and one or a plurality of the above-described storage devices according to an embodiment of the present disclosure disposed at an intersection of the first wiring line and the second wiring line.

In the storage device and the storage unit according to respective embodiments of the present disclosure, there are provided: the storage layer including at least copper, aluminum, zirconium, and tellurium; and the barrier layer including, between the storage layer and the second electrode, zirconium at a higher concentration than at least the storage layer, and having a copper concentration, at an interface with the second electrode, being lower than the storage layer. This improves adhesiveness of the second electrode to a lower layer.

### BRIEF DESCRIPTION OF THE DRAWINGS

FIG. 1 is a schematic cross-sectional view of an example of a configuration of a memory device according to an embodiment of the present disclosure.

FIG. 2 illustrates an example of an outline configuration of a memory cell array according to an embodiment of the present disclosure.

FIG. 3 is a schematic cross-sectional view of another example of the configuration of the memory device illustrated in FIG. 1.

FIG. 4A is a schematic cross-sectional view of an example of a configuration of a switch device illustrated in FIG. 2.

FIG. 4B is a schematic cross-sectional view of another example of the configuration of the switch device illustrated in FIG. 2.

FIG. 5A is a schematic cross-sectional view of an example of a configuration of a memory cell illustrated in FIG. 2.

FIG. 5B is a schematic cross-sectional view of another example of the configuration of the memory cell illustrated in FIG. 2.

FIG. 5C is a schematic cross-sectional view of another example of the configuration of the memory cell illustrated in FIG. 2.

FIG. 5D is a schematic cross-sectional view of another example of the configuration of the memory cell illustrated in FIG. 2.

FIG. 6A is a perspective view of an example of the configuration of the memory cell illustrated in FIG. 5A.

FIG. 6B is a schematic view of a cross-sectional configuration of the memory cell illustrated in FIG. 6A.

FIG. 7A is a perspective view of an example of the configuration of the memory cell illustrated in FIG. 5D.

FIG. 7B is a schematic view of a cross-sectional configuration of the memory cell illustrated in FIG. 7A.

FIG. 8A is a schematic view of a cross-sectional configuration of the memory cell illustrated in FIG. 5C.

FIG. 8B is a schematic view of a cross-sectional configuration of the memory cell illustrated in FIG. 5C as a comparative example.

FIG. 9 illustrates an example of an outline configuration of a memory cell array in a modification example of the present disclosure.

FIG. 10 illustrates another example of the outline configuration of the memory cell array in a modification example of the present disclosure.

FIG. 11 illustrates another example of the outline configuration of the memory cell array in a modification example of the present disclosure.

FIG. 12 illustrates another example of the outline configuration of the memory cell array in a modification example of the present disclosure.

FIG. 13 describes a compositional range of Te, Al, and Zr included in a barrier layer of the present disclosure.

### MODES FOR CARRYING OUT THE INVENTION

Hereinafter, description is given in detail of an embodiment of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.

1. Embodiment (An example of a memory device including, between a storage layer and an upper electrode, a barrier layer including zirconium at a higher concentration than the storage layer)

1-1. Configuration of Memory Device

1-2. Configuration of Memory Cell Array

1-3. Workings and Effects

2. Modification example (An example of a three-dimensionally structured memory cell array)

### 3. Example

### 1. Embodiment

### (1-1. Configuration of Memory Device)

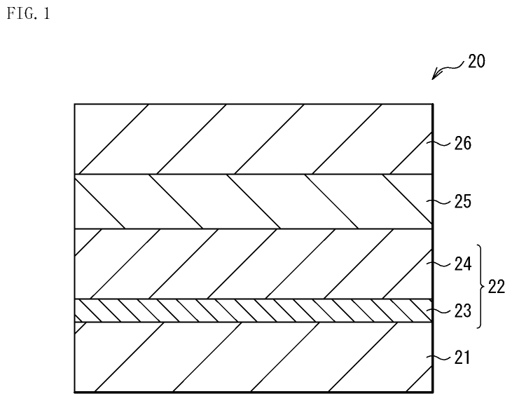

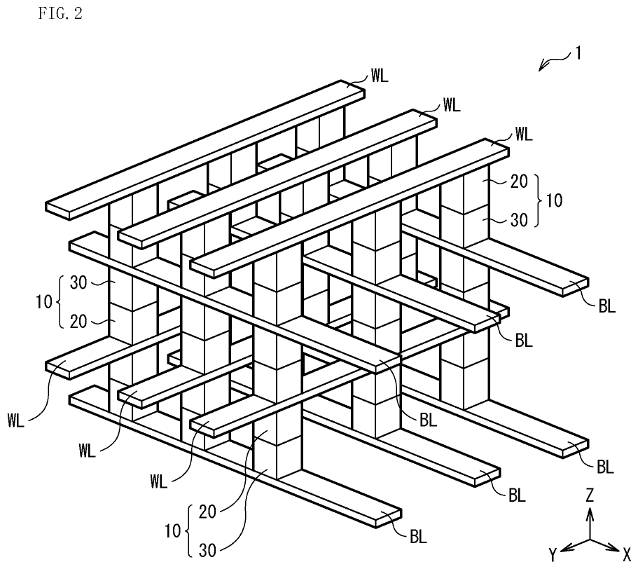

FIG. 1 illustrates an example of a cross-sectional configuration of a storage device (a memory device 20) according to an embodiment of the present disclosure. The memory device 20 is used for a memory cell array 1 having a so-called cross-point array structure, for example, illustrated in FIG. 2. The memory device 20 includes a lower electrode 21, a storage layer 22, a barrier layer 25, and an upper electrode 26, in this order. In the present embodiment, the storage layer 22 includes, for example, copper (Cu), aluminum (Al), zirconium (Zr), and tellurium (Te), and the barrier layer 25 is formed to include zirconium (Zr) at a higher concentration than that of the storage layer 22, with an interface in contact with the upper electrode 26 having a copper (Cu) concentration lower than that of the storage layer 22.

The lower electrode 21 is formed by, for example, a wiring material to be used in semiconductor processes, and corresponds to a specific example of a “first electrode” of the present disclosure. Specifically, the lower electrode 21 may be formed, for example, using tungsten (W), tungsten nitride (WN), titanium nitride (TiN), copper (Cu), aluminum (Al), molybdenum (Mo), tantalum (Ta), tantalum nitride (TaN), silicide, and the like. In a case where the lower electrode 21 includes a material such as Cu, which may possibly cause ion conduction in an electric field, a front surface of the lower electrode 21 may be coated with a material unlikely to cause ion conduction or thermal diffusion. Examples of the material unlikely to cause ion conduction or thermal diffusion include tungsten (W), tungsten nitride (WN), titanium nitride (TiN), tantalum nitride (TaN), titanium tungsten (TiW), titanium tungsten nitride (TiWN), and the like.

The storage layer 22 includes, from side of the lower electrode 21, a resistance change layer 23 and an ion source layer 24 stacked in this order.

In the resistance change layer 23, a resistance value is changed by applying a voltage equal to or more than a predetermined voltage between the lower electrode 21 and the upper electrode 26. The resistance change layer 23 includes, for example, one of an oxide, a nitride, or an oxynitride of a metal element or non-metal element. Specifically, the resistance change layer 23 may be formed using, for example, an oxide including aluminum (Al).

For example, when a voltage equal to or more than a predetermined voltage is applied between the lower electrode 21 and the upper electrode 26, a movable element (e.g., a transition metal element) included in the ion source layer 24 described later moves into the resistance change layer 23 to form a conductive path, thereby causing the resistance change layer 23 to have lower resistance. In addition, a structural defect such as oxygen defect or nitrogen defect occurs in the resistance change layer 23 to generate a conductive path, which causes the resistance change layer 23 to have lower resistance. In addition, by applying a voltage in a direction opposite to a direction of the voltage applied when the resistance change layer 23 is caused to have lower resistance, a conductive path is cut, or the conductivity is changed, thus causing the resistance change layer 23 to have higher resistance.

It is to be noted that all of metal elements and non-metal elements included in the resistance change layer 23 may not necessarily be in a state of an oxide, but some of them may be in an oxidized state. In addition, when a device resistance of, for example, several MΩ to several hundred MΩ is achieved in an initial state, the resistance change layer 23 may be formed using a metal element other than aluminum (Al) or a non-metal element. Further, the resistance change layer 23 may include the following additive elements. Examples of the additive elements include tungsten (W), hafnium (Hf), carbon (C), silicon (Si), magnesium (Mg), tantalum (Ta), copper (Cu), nickel (Ni), zirconium (Zr), gadolinium (Gd), and the like.

Further, the resistance change layer 23 may be formed as a stacked film of an insulating layer including an oxide and a nitride of a metal element or a non-metal element. Furthermore, in the resistance change layer 23, it is sufficient that a device resistance of, for example, several MΩ to several hundred MΩ is achieved in an initial state; a thickness thereof is preferably, for example, 1 nm or more and about 10 nm, although an optimum value thereof is changed depending on a size of the memory device 20 and a resistance value of the ion source layer 24.

In addition, the resistance change layer 23 need not necessarily be formed actively. During a manufacturing operation of the memory device 20, oxygen and a transition metal element included in the ion source layer 24 are combined with each other, thus naturally forming an oxide film corresponding to the resistance change layer 23 between the lower electrode 21 and the ion source layer 24. Alternatively, an oxide film formed by application of a voltage bias in an erasing direction corresponds to the resistance change layer 23.

The ion source layer 24 is formed to include an element (movable element) that forms the conductive path inside the resistance change layer 23 by the application of a voltage equal to or more than a predetermined voltage between the lower electrode 21 and the upper electrode 26. The movable element is cationized or anionized by application of an electric field, and is moved into the resistance change layer 23 to form the conductive path. Examples of the movable elements to be cationized include transition metal elements, in particular, metal elements of Periodic Table Group 4 (Titanium (Ti), zirconium (Zr), and hafnium (Hf)), Group 5 (vanadium (V), niobium (Nb), and tantalum (Ta)), and Group 6 (chromium (Cr), molybdenum (Mo), and tungsten (W)), and copper (Cu). Other examples thereof include aluminum (Al). Examples of the movable element to be anionized include Periodic Table Group 16 elements, specifically, chalcogen elements such as tellurium (Te), sulfur (S), and selenium (Se). The above-mentioned transition metal elements are relatively chemically stable in a chalcogen matrix, thus enhancing stability of the conductive path in a state of being in contact with the chalcogen element. The ion source layer 24 may be formed to include one or two or more types of each of the cationic elements and the anionic elements.

Further, the ion source layer 24 may include oxygen (O), nitrogen (N), a metal element other than the above-mentioned movable element (e.g., metal element such as manganese (Mn), cobalt (Co), iron (Fe), nickel (Ni), and platinum (Pt)), silicon (Si), or the like.

The barrier layer 25 is provided for improving adhesiveness between the storage layer 22 (specifically, the ion source layer 24) and the upper electrode 26. The adhesiveness between the storage layer 22 and the upper electrode 26 is influenced by a composition of the barrier layer 25 as well as an average composition ratio including compositions of the ion source layer 24 and the barrier layer 25, and a film thickness in the stacking direction (hereinafter, simply referred to as a thickness) of each of the ion source layer 24 and the barrier layer 25.

For example, the barrier layer 25 may be formed using an element other than copper (Cu) among the elements included in the ion source layer 24. In this manner, forming the ion source layer 24 and the barrier layer 25 using the same element makes it possible to avoid complicated working conditions in the manufacturing operation of the memory device 20.

Examples of a specific composition of the barrier layer 25 include the following configuration. For example, the barrier layer 25 includes zirconium (Zr), and has a tellurium (Te) concentration of less than 42.5 atomic percent among three elements of tellurium (Te), aluminum (Al), and zirconium (Zr) excluding copper (Cu) in the average composition ratio of the barrier layer 25 and the ion source layer 24. Causing the barrier layer 25 and the ion source layer 24 to satisfy the above conditions improves the adhesiveness between the ion source layer 24 and the upper electrode 26.

The barrier layer 25 includes, for example, zirconium (Zr) and tellurium (Te); the barrier layer 25 has a zirconium (Zr) concentration of 59.4 atomic percent or more and less than 100 atomic percent, and has a tellurium (Te) concentration of less than 42.5 atomic percent among the three elements of tellurium (Te), aluminum (Al), and zirconium (Zr) excluding copper (Cu) in the average composition ratio of the barrier layer 25 and the ion source layer 24. Causing the barrier layer 25 and the ion source layer 24 to satisfy the above conditions improve the adhesiveness between the ion source layer 24 and the upper electrode 26.

In addition, the barrier layer 25 includes, for example, zirconium (Zr), tellurium (Te), and aluminum (Al); the barrier layer 25 has a zirconium (Zr) concentration of 40 atomic percent or more, has a concentration ratio (Te/Al) between tellurium (Te) and aluminum (Al) of 1.0 or more, and has a tellurium (Te) concentration of less than 42.5 atomic percent. Satisfying the above conditions improves the adhesiveness between the ion source layer 24 and the upper electrode 26.

In addition, the barrier layer 25 includes, for example, zirconium (Zr), tellurium (Te), and aluminum (Al); the barrier layer 25 has a zirconium (Zr) concentration of 18.5 atomic percent or more and 36 atomic percent or less, and has a concentration ratio (Te/Al) between tellurium (Te) and aluminum (Al) of 0.64 or more and 1.0 or less. Satisfying the above condition improves the adhesiveness between the ion source layer 24 and the upper electrode 26.

It is to be noted that thickness of the barrier layer 25 in the above conditions is set to, for example, 2 nm or more and 12 nm or less. In addition, the total thickness of the barrier layer 25 and the ion source layer 24 is set to, for example, 15 nm or more and 25 nm or less.

Further, the barrier layer 25 may include elements other than zirconium (Zr), tellurium (Te), and aluminum (Al) in such an extent that the effects of the present disclosure are not impaired.

Satisfying the above condition enables the barrier layer 25 to reduce diffusion of copper (Cu) from the ion source layer 24 to the upper electrode 26. For example, the copper (Cu) concentration at the interface between the barrier layer 25 and the upper electrode 26 is 0 atomic percent, or is lower than a copper (Cu) concentration of the storage layer 22 (specifically, the ion source layer 24). This improves the adhesiveness between the storage layer 22 (specifically, the ion source layer 24) and the upper electrode 26, thus enabling fine working of the memory device 20.

It is to be noted that the barrier layer 25 may be confirmed by elemental analysis using, for example, secondary ion mass spectrometry (SIMS) or an energy-dispersive X-ray analysis method (TEM-EDX).

The upper electrode 26 corresponds to a specific example of a “second electrode” of the present disclosure; for example, a known semiconductor wiring material may be used similarly to the lower electrode 21, but a stable material is preferable which does not react with the ion source layer 24 even after going through post-annealing. Specifically, the upper electrode 26 may be formed to include tungsten (W), for example.

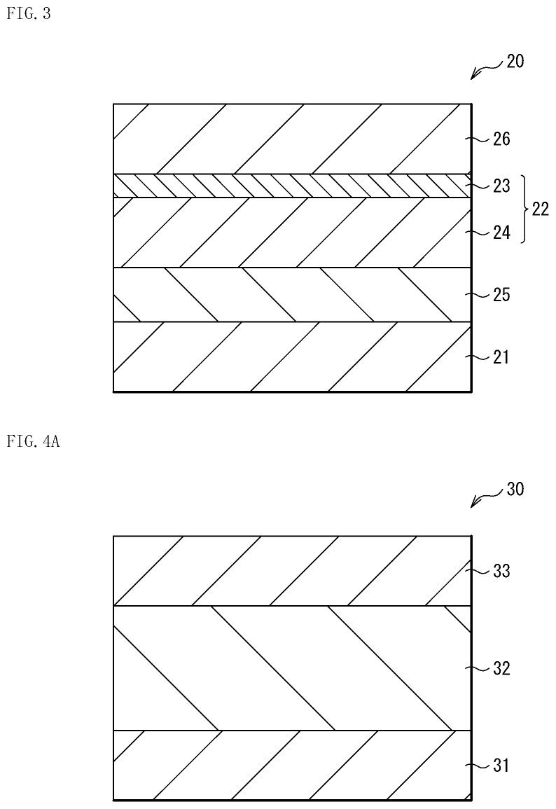

It is to be noted that FIG. 1 illustrates an example in which the storage layer 22 including the resistance change layer 23 and the ion source layer 24, the barrier layer 25, and the upper electrode 26 are stacked in this order on the lower electrode 21; however, this is not limitative. As for the memory device 20, for example, as illustrated in FIG. 3, the memory device 20 may have a configuration in which the barrier layer 25, the storage layer 22, and the upper electrode 26 are stacked in order on the lower electrode 21. In such an occasion, the lower electrode 21 corresponds to a specific example of a “second electrode” of the present disclosure, and the upper electrode 26 corresponds to a specific example of a “first electrode” of the present disclosure. In addition, the resistance change layer 23 included in the storage layer 22 is provided on the side of the lower electrode 21, and the ion source layer 24 is provided to be in contact with the barrier layer 25.

### (1-2. Configuration of Memory Cell Array)

FIG. 2 illustrates an example of a configuration of the memory cell array 1 in a perspective manner. The memory cell array 1 corresponds to a specific example of a “storage unit” of the present disclosure. The memory cell array 1 includes a so-called cross-point array structure, and includes, for example, one memory cell 10 at a position (cross-point) where each word line WL and each bit line BL face each other as illustrated in FIG. 2. That is, the memory cell array 1 includes a plurality of word lines WL, a plurality of bit lines BL, and a plurality of memory cells 10 arranged one by one for respective cross-points. The word line WL and the bit line BL correspond to specific examples of a “first wiring line” and a “second wiring line” of the present disclosure, respectively.

The word lines WL extend in a direction common to each other. The bit lines BL extend in a direction different from the extending direction of the word line WL (e.g., in a direction orthogonal to the extending direction of the word line WL) and in a direction common to each other. It is to be noted that the plurality of word lines WL and the plurality of bit lines BL are each arranged in one or a plurality of layers, and may be arranged separately in a plurality of levels, for example.

For example, as illustrated in FIG. 2, in a case where the plurality of word lines WL are arranged in a plurality of levels, the plurality of bit lines BL are arranged between a first layer in which the plurality of word lines WL are arranged and a second layer adjacent to the first layer in which the plurality of word lines WL are arranged. In a case where the plurality of bit lines BL are arranged in a plurality of levels, the plurality of word lines WL are arranged between a third layer in which the plurality of bit lines BL are arranged and a fourth layer adjacent to the third layer in which the plurality of bit lines BL are arranged. That is, in a case where the plurality of word lines WL and the plurality of bit lines BL are each arranged separately in a plurality of levels, the plurality of word lines WL and the plurality of bit lines BL are alternately arranged in a stacking direction (e.g., a Z-axis direction) of the memory cell array 1.

In the memory cell array 1, the plurality of word lines WL and the plurality of bit lines BL are arranged separately in one or a plurality of levels on a substrate (unillustrated), and the memory cells 10 are arranged two-dimensionally or three-dimensionally at the respective cross-points. For example, a wiring group electrically coupled to the word line WL and the bit line BL, and a circuit or the like to link the wiring group and an external circuit together are further formed on the substrate.

The memory cell 10 includes, for example, the memory device 20 and a switch device 30, and one memory cell 10 is disposed at the cross-point between each word line WL and each bit line BL as described above.

FIG. 4A illustrates an example of a cross-sectional configuration of the switch device 30 in a schematic manner. In the memory cell array 1 illustrated in FIG. 2, for example, the switch device 30 is provided to selectively operate any memory device of the plurality of memory devices 20 disposed at the respective cross-points between the plurality of word lines WL and the plurality of bit lines BL. Specifically, the switch device 30 comes into a low-resistance state by setting an applied voltage to a predetermined threshold voltage or more, and comes into a high-resistance state by setting the applied voltage to less than the predetermined threshold voltage, without going through a phase change between an amorphous phase and a crystalline phase. The switch device 30 has a configuration in which, for example, a lower electrode 31, a switch layer 32, and an upper electrode 33 are stacked in this order.

Similarly to the lower electrode 21 of the memory device 20, the lower electrode 31 may be formed by, for example, a wiring material to be used in semiconductor processes. Specifically, the lower electrode 31 may be formed using, for example, tungsten (W), tungsten nitride (WN), titanium nitride (TiN), copper (Cu), aluminum (Al), molybdenum (Mo), tantalum (Ta), tantalum nitride (TaN), silicide, and the like. In a case where the lower electrode 31 includes a material such as Cu, which may possibly cause ion conduction in an electric field, a front surface of the lower electrode 31 may be coated with a material unlikely to cause ion conduction or thermal diffusion. Examples of the material unlikely to cause ion conduction or thermal diffusion include tungsten (W), tungsten nitride (WN), titanium nitride (TiN), tantalum nitride (TaN), titanium tungsten (TiW), titanium tungsten nitride (TiWN), and the like.

The switch layer 32 comes into a low-resistance state by setting an applied voltage to a predetermined threshold voltage (switching threshold voltage) or more, and comes into a high-resistance state by setting the applied voltage to less than the switching threshold voltage. In addition, the switch layer 32 has negative differential resistance characteristics, and flows a current several orders of magnitude when a voltage to be applied to the switch device 30A exceeds the predetermined threshold voltage (switching threshold voltage).

In addition, as for the switch layer 32, regardless of application of a voltage pulse or a current pulse via the lower electrode 31 and the upper electrode 33 from an unillustrated power circuit (pulse applying means), an amorphous structure of the switch layer 32 is stably maintained. It is to be noted that the switch layer 32 does not perform such a memory operation that a conductive path formed by movement of ions by voltage application is maintained after erasure of the applied voltage.

The switch layer 32 may be formed to include elements of Periodic Table Group 16, specifically, at least one type of a chalcogen element selected from tellurium (Te), selenium (Se), and sulfur (S). In the switch device 30 having an OTS (Ovonic Threshold Switch) phenomenon, it is preferable for the switch layer 32 to stably maintain the amorphous structure without going through a phase change even when applying a voltage bias for switching; as the amorphous structure becomes more stable, it is possible to stably generate the OTS phenomenon. The switch layer 32 is preferably formed to include at least one type of an additive element selected from boron (B), carbon (C), and silicon (Si), in addition to the chalcogen element described above. The switch layer 32 is preferably formed to further include nitrogen (N). Specifically, the switch layer 32 is preferably formed to include a composition of any of BTe, CTe, BCTe, CSiTe, BSiTe, BCSiTe, BTeN, CTeN, BCTeN, CSiTeN, BSiTeN, and BCSiTeN.

The switch layer 32 functions as a bidirectional switch. For example, when a voltage (a first voltage V1) at which a voltage of the lower electrode 31 is higher than a voltage of the upper electrode 33 is applied between the lower electrode 31 and the upper electrode 33, an absolute value of the first voltage V1 is increased to a first threshold voltage or more to thereby change the switch layer 32 into a low-resistance state, and the absolute value of the first voltage V1 is decreased to less than the first threshold voltage to thereby change the switch layer 32 into a high-resistance state. Further, when a voltage (a second voltage V2) at which the voltage of the upper electrode 33 is higher than the voltage of the lower electrode 31 is applied between the lower electrode 31 and the upper electrode 33, an absolute value of the second voltage V2 is increased to a second threshold voltage or more to thereby change the switch layer 32 into a low-resistance state, and the absolute value of the second voltage V2 is decreased to less than the second threshold voltage to thereby change the switch layer 32 into a high-resistance state.

In addition, an absolute value of a voltage (a third voltage V3) between the lower electrode 31 and the upper electrode 33 at the time when a writing voltage Vw, which causes the memory cell 10 to have lower resistance, is applied to the memory cell 10 is increased to a third threshold voltage or more to thereby change the switch layer 32 into a low-resistance state, and the absolute value of the third voltage V3 is decreased to less than the third threshold voltage to thereby change the switch layer 32 into a high-resistance state. An absolute value of a voltage (a fourth voltage V4) between the lower electrode 31 and the upper electrode 33 at the time when an erasing voltage Vr, which causes the memory cell 10 to have higher resistance, is applied to the memory cell 10 is increased to a fourth threshold voltage or more to thereby change the switch layer 32 into a low-resistance state, and the absolute value of the fourth voltage V4 is decreased to less than the fourth threshold voltage to thereby change the switch layer 32 into a high-resistance state.

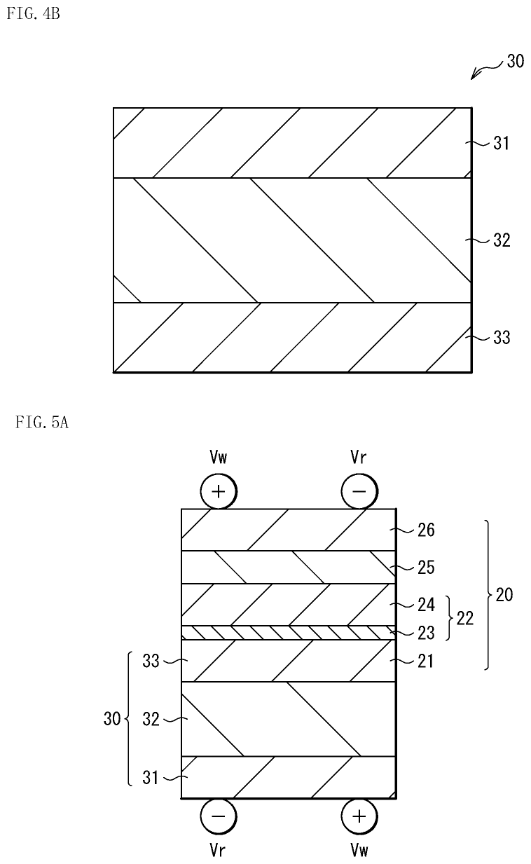

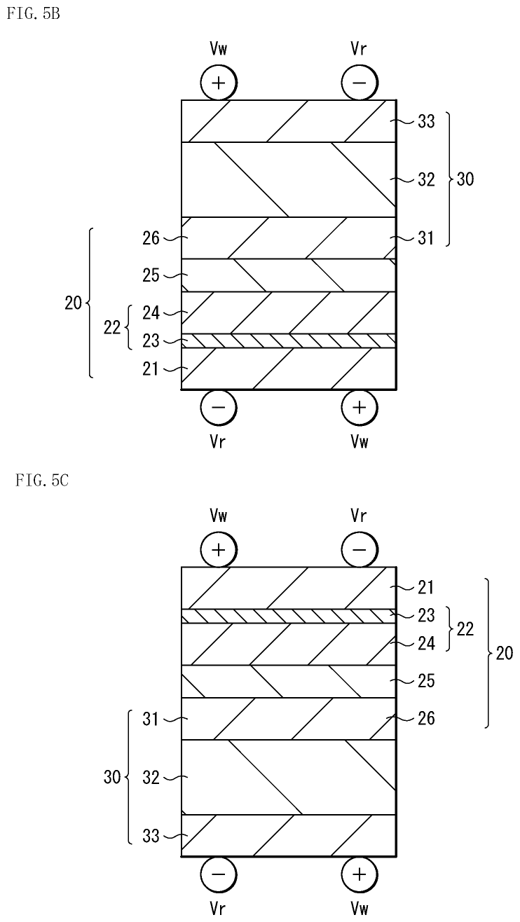

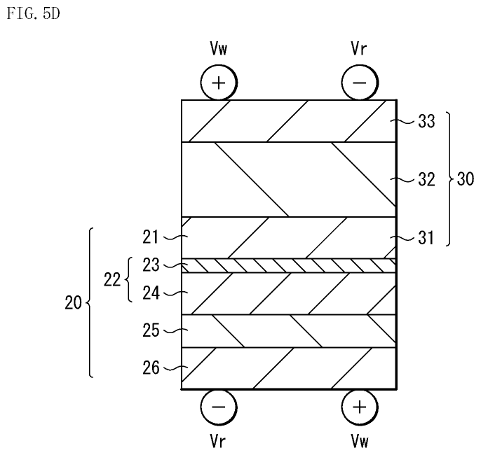

As illustrated in FIGS. 5A to 5D for example, in the memory cell 10, the switch device 30 is directly coupled to the memory device 20. That is, for example, in FIGS. 5A to 5D, suppose that the bit line BL is disposed at a lower location and the word line WL is disposed at an upper location, the memory device 20 is disposed closer to the word line WL, for example, while the switch device 30 is disposed closer to the bit line BL, for example, as illustrated in FIGS. 5A and 5C. In addition, as illustrated in FIGS. 5B and 5D, the memory device 20 may be disposed closer to the bit line BL, for example, while the switch device 30 may be disposed closer to the word line WL, for example.

In a case where the memory cell 10 is configured using the memory device 20 and the switch device 30 described above, the lower electrodes 21 and 31 and the upper electrodes 26 and 33 disposed in the lowermost layer and the uppermost layer of the memory device 20 and the switch device 30 may serve also as the word line WL and the bit line BL depending on the stacking order. In addition, the lower electrodes 21 and 31 and the upper electrodes 26 and 33 arranged in the lowermost layer and the uppermost layer may be formed separately from the word line WL and the bit line BL.

For example, as illustrated in FIG. 5A, in a case where the switch device 30 and the memory device 20 are stacked in this order between the bit line BL and the word line WL, for example, the lower electrode 31 of the switch device 30 may serve also as the bit line BL, while the upper electrode 26 of the memory device 20 may serve also as the word line WL. In addition, the lower electrode 31 and the bit line BL as well as the upper electrode 26 and the word line WL may be formed separately from each other. It is to be noted that, in a case where they are formed separately from each other, the lower electrode 31 and the bit line BL as well as the upper electrode 26 and the word line WL are electrically coupled to each other.

In addition, in a case where the memory cell 10 is configured using the memory device 20 and the switch device 30 described above, the electrodes stacked on each other between the memory device 20 and the switch device 30 (e.g., the upper electrode 33 of the switch device 30 and the lower electrode 21 of the memory device 20 in a case where the switch device 30 and the memory device 20 are stacked in this order as illustrated in FIG. 5A) may serve also as an upper electrode and a lower electrode, which function as intermediate electrodes, respectively, or may be each formed separately therefrom.

In a case of forming, between the memory device 20 and the switch device 30, intermediate electrodes serving also as an upper electrode and lower electrode thereof, the intermediate electrodes are preferably formed using, for example, a material that prevents diffusion of a chalcogen element included in the ion source layer 24 and the switch layer 32 by application of an electric field. One reason for this is, for example, that, in a case where a transition metal element is included in the ion source layer 24 as an element to perform memory operation and keep a writing condition, diffusion of the transition metal element into the switch layers 32 by application of an electric field may possibly cause deterioration of switch characteristics. Accordingly, the intermediate electrode preferably includes a barrier material having a barrier property to prevent the diffusion of the transition metal element and ion conduction. Examples of the barrier material include tungsten (W), tungsten nitride (WN), titanium nitride (TiN), carbon (C), tantalum (Ta), tantalum nitride (TaN), titanium tungsten (TiW), and the like.

In addition, the stacking order of the resistance change layer 23, the ion source layer 24, and the barrier layer 25 inside the memory cell 10 is not particularly limited, as long as the resistance change layer 23 is disposed on side of one electrode and the barrier layer 25 is disposed on side of the other electrode opposed to the one electrode, with the ion source layer 24 interposed therebetween, as illustrated in FIGS. 5A to 5D.

Further, FIG. 2 illustrates an example in which the memory device 20 is formed independently for each cross-point between the word line WL and the bit line BL; however, the memory device 20 may be formed as a common device extending in one direction, similarly to the word line WL and the bit line BL.

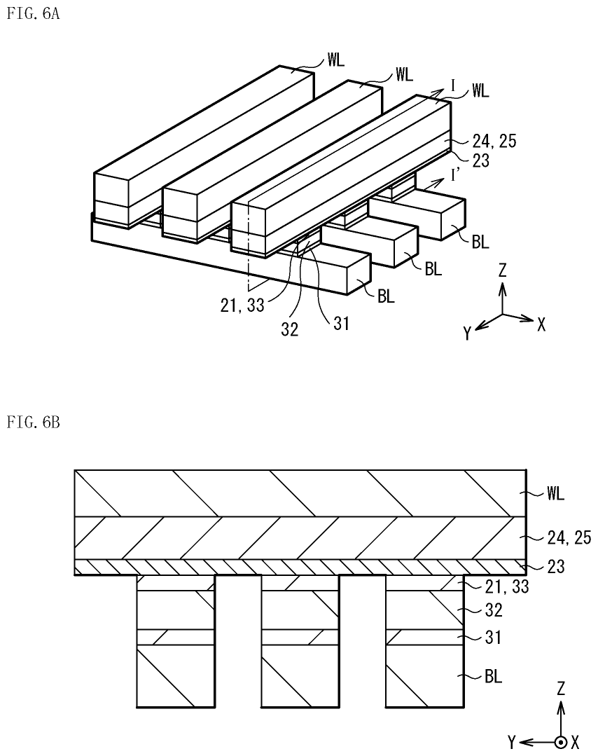

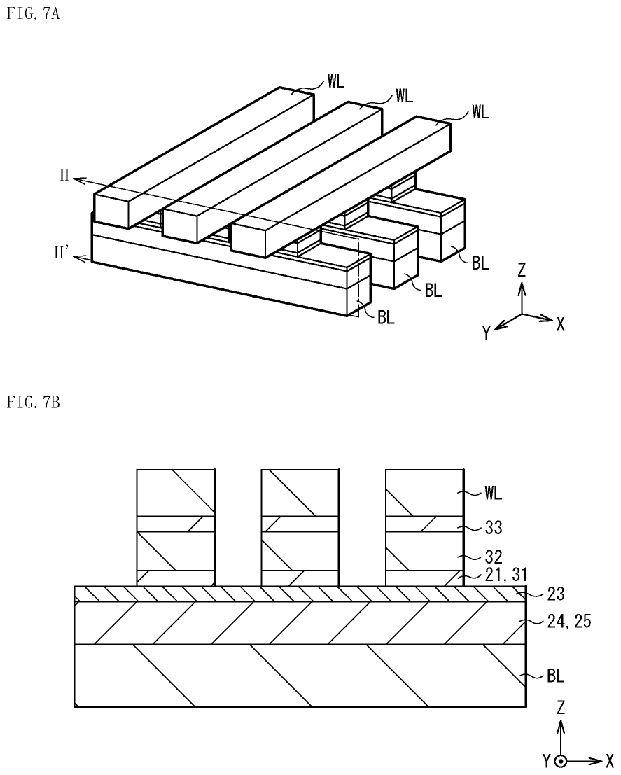

For example, as illustrated in FIG. 5A, in a case where the switch device 30 and the memory device 20 are stacked in this order between the bit line BL and the word line WL and where the resistance change layer 23 is disposed on side of the switch device 30, for example, the resistance change layer 23, the ion source layer 24, and the barrier layer 25, which are included in the memory device 20, may extend in a Y-axis direction similarly to the word line WL and may be formed as a common layer to the memory cells 10, as illustrated in FIGS. 6A and 6B. It is to be noted that, in FIGS. 6A and 6B, the word line WL is structured to serve also as the upper electrode 26 of the memory device 20. In addition, FIG. 6B illustrates a cross-sectional configuration along a line I-I′ illustrated in FIG. 6A. Likewise, as illustrated in FIG. 5D, in a case where the memory device 20 and the switch device 30 are stacked in this order between the bit line BL and the word line WL and where the resistance change layer 23 is disposed on the side of the switch device 30, for example, the resistance change layer 23, the ion source layer 24, and the barrier layer 25, which are included in the memory device 20, may extend in an X-axis direction similarly to the bit line BL and may be formed as a common layer to the memory cells 10, as illustrated in FIGS. 7A and 7B. It is to be noted that, in FIGS. 7A and 7B, the bit line BL is structured to serve also as the lower electrode 21 of the memory device 20. In addition, FIG. 7B illustrates a cross-sectional configuration along a line II-II′ illustrated in FIG. 7A.

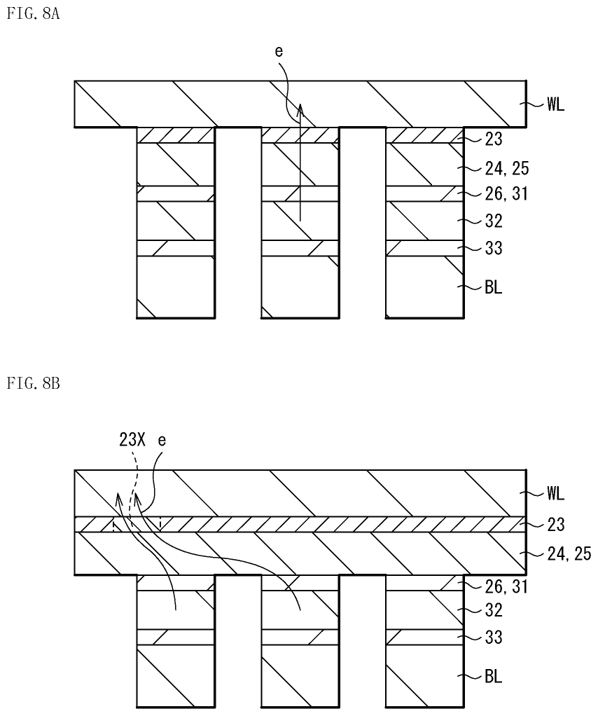

However, in a case where the resistance change layer 23 is not disposed on the side of the switch device 30, i.e., the resistance change layer 23 is disposed closer to the bit line BL (FIG. 5B) or to the word line (WL) (FIG. 5C) as illustrated in FIGS. 5B and 5C, the memory device 20 is preferably formed for each cross-point similarly to the switch device 30 as illustrated in the FIG. 8A. One reason for this is that, as illustrated in FIG. 8B, for example, when there is a low-resistance portion (a low-resistance part 23X) in the resistance change layer 23 formed continuously closer to the word line WL, a current “e” flows selectively to the low-resistance part 23X via the barrier layer 25 and the ion source layer 24 that are successive, making it unable to make a determination and to perform an operation for each memory device 20. As illustrated in FIGS. 5A and 5D, in a case where the resistance change layer 23 is disposed on the side of the switch device 30, a current flowing from the switch device 30 to the memory device 20 always passes through the resistance change layer 23, thus making it possible to have the structure as illustrated in FIG. 6A and FIG. 7A, etc.

### (1-3. Workings and Effects)

In the memory device 20 of the present embodiment, the barrier layer 25, which includes zirconium (Zr) at a higher concentration than at least that of the ion source layer 24 and has the copper (Cu) concentration lower than that of the ion source layer 24 at the interface with the upper electrode 26, is provided between the upper electrode 26 and the storage layer 22 (specifically, the ion source layer 24) formed to include at least copper (Cu), aluminum (Al), zirconium (Zr), and tellurium (Te). This improves the adhesiveness between the ion source layer 24 and the upper electrode 26. This is to be described below.

In an information apparatus such as a computer, a DRAM (Dynamic Random Access Memory) having high-speed operation and high density has been widely used as a random-access memory. However, as for the DRAM, the manufacturing process is complicated as compared with a typical logical circuit LSI (Large Scale Integrated circuit) or a signal processing circuit used in electronic apparatuses, thus causing the manufacturing costs to be higher. In addition, the DRAM is a volatile memory of which information disappears when a power source is turned off, and needs to frequently perform refresh operations, i.e., needs to frequently perform operations to read, reamplify, and rewrite written (information) data again.

Therefore, there have been proposed, as a non-volatile memory in which no information disappears even when a power source is turned off, for example, a flash memory, a FeRAM (Ferroelectric Random Access Memory) (ferroelectric memory), an MRAM (Magnetoresistive Random Access Memory (magnetic storage device), or the like. In the case of these memories, it is possible to keep holding written information for a long period of time without supplying power. However, each of these memories has advantages and disadvantages. For example, the flash memory has a high degree of integration but has a disadvantage in terms of an operation speed. The FeRAM has a limitation in terms of fine working due to a higher degree of integration, and has an issue of fabrication processes. The MRAM has an issue of power consumption.

Therefore, new types of storage devices, such as a ReRAM and a PCM, have been proposed as next-generation non-volatile memories. Further, a storage device has also been proposed which enables low-current operation, in order to achieve larger capacity of memories.

Incidentally, in the storage device as described above, copper (Cu) is used as an ion source for the memory operation. Copper (Cu) is known as a material difficult to be etched in gas-reactive dry etching used in device working, but is workable by appropriately selecting a condition in a case where the concentration is low and the ion source layer is thin. However, copper (Cu) is an element easy to diffuse, and may diffuse to a layer other than the ion source layer, in particular, an electrode layer in contact with the ion source layer, in some cases.

Normally, it is possible to work the electrode layer using dry etching unless a special material is used for the electrode layer; however, the diffusion of copper (Cu) makes it difficult to perform the working. In addition, in the case of the cross-point array structure used in the high-capacity memory, no access transistor is disposed in each storage device, and a large number of storage devices are coupled to a wiring line of a certain length to be coupled to a readout circuit and a write circuit. For this reason, when the resistance value of a wiring line is large, a voltage drop in the wiring line becomes unignorable depending on the position of the storage device, as compared with the voltage required for the memory operation. In order to keep the resistance value of the wiring line low, a low-resistivity material is used, and the thickness of the wiring line is set as thick as possible. Here, in a case where the electrode layer is used as it is in the wiring layer, the electrode layer is set to be thick; however, when copper (Cu) diffuses thereto, it becomes more difficult to perform the working than the ion source layer. Specifically, the etching rate becomes very slow, thus making it necessary to increase the thickness of a mask material that defines the shapes such as a wiring line width. The working by dry etching becomes more difficult as the pattern becomes finer, because of a larger ratio between the width and the thickness, i.e., a larger ratio between the wiring line width and the etching depth.

In order to prevent the diffusion of copper (Cu) from the ion source layer to the electrode layer, it is conceivable to provide a barrier layer between the ion source layer and the electrode layer. However, depending on selection of the material and the structure of the barrier layer, the electrode layer may possibly undergo detachment of a film.

Meanwhile, in the memory device 20 of the present embodiment, the barrier layer 25 including zirconium (Zr) at a higher concentration than at least the ion source layer 24 is provided between the ion source layer 24 and the upper electrode 26, thus improving the adhesiveness between the ion source layer 24 and the upper electrode 26. In addition, in the barrier layer having such a configuration, the copper (Cu) concentration at the interface of the barrier layer 25 with the upper electrode 26 is lower than that of the ion source layer 24. That is, providing the barrier layer 25 having the above-described configuration between the ion source layer 24 and the upper electrode 26 makes it possible to improve the adhesiveness between the ion source layer 24 and the upper electrode 26 while reducing the diffusion of copper (Cu) from the ion source layer 24 to the upper electrode 26.

As described above, in the present embodiment, it is possible to achieve the memory device 20 superior in workability by etching, and thus to provide the memory cell array 1 having high density and large capacity.

Next, description is given of a modification example in the foregoing embodiment. In the following description, components similar to those of the foregoing embodiment are denoted by the same reference numerals, and descriptions thereof are omitted as appropriate.

### 2. Modification Example

In the memory cell array 1 in the foregoing embodiment, the example has been given, in which the plurality of word lines WL extending in the Y-axis direction and the plurality of bit lines BL extending in the X-axis direction are arranged alternately and separately in a plurality of layers, and the memory cell 10 is disposed at each cross-point; however, this is not limitative. The memory device 20 and the memory cell 10 of the present disclosure are also applicable, for example, to a three-dimensionally structured memory cell as described below.

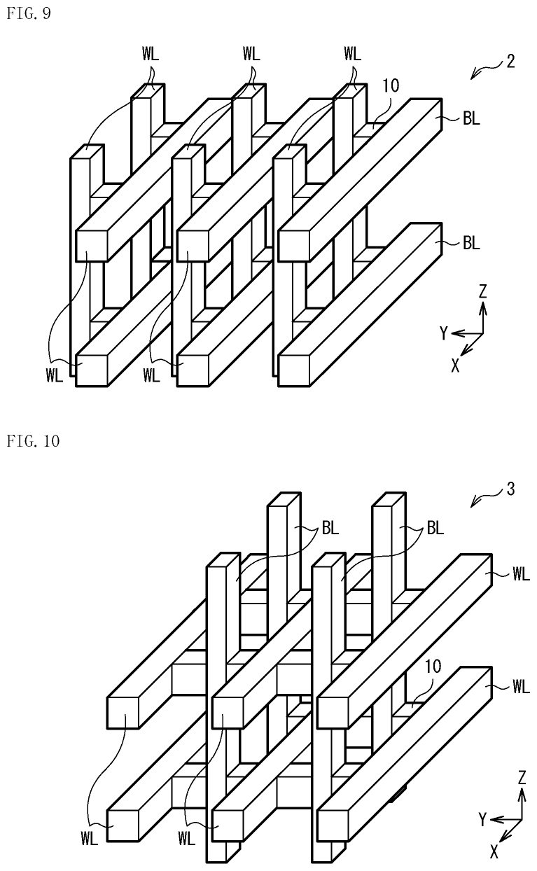

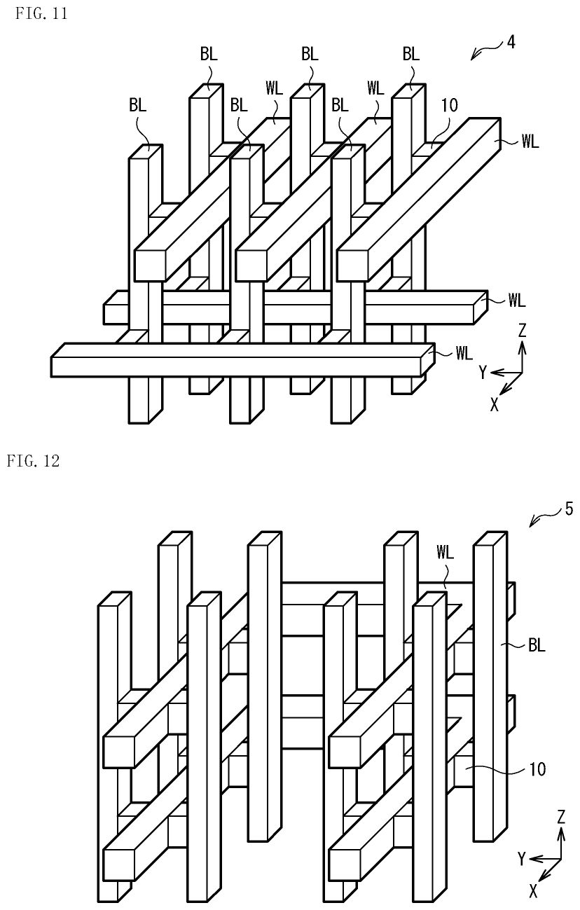

In a memory cell array 2 illustrated in FIG. 9, each of the plurality of word lines WL extends in the X-axis direction and each of the plurality of bit lines BL extends in the Z-axis direction, and the memory cell 10 is disposed at each cross-point. In a memory cell array 3 illustrated in FIG. 10, similarly to the memory cell array 1, the memory cells 10 are disposed on both surfaces of each of cross-points between the plurality of word lines WL and the plurality of bit lines BL extending in the X-axis direction and the Z-axis direction, respectively. A memory cell array 4 illustrated in FIG. 11 includes the plurality of bit lines BL extending in the Z-axis direction and two types of the plurality of word lines WL extending in two directions of the X-axis direction or the Y-axis direction, and the memory cell 10 is disposed at each cross-point. In a memory cell array 5 illustrated in FIG. 12, the plurality of bit lines BL extend in the Z-axis direction, and the plurality of word lines WL extend in the X-axis direction, bend midway in the Y-axis direction, and further bend in the X-axis direction to extend in a so-called U-shape in an X-Y plane, and the memory cell 10 is disposed at each cross-point.

As described above, the memory device 20 of the foregoing embodiment and the memory cell 10 including the memory device 20 are also applicable to a so-called vertical cross-point-structured memory cell array (e.g., the memory cell arrays 2 to 5) in which either one of the word line WL or the bit line BL is provided in parallel with the Z-axis direction and the other thereof is provided in parallel with the X-Y planar direction. In addition, the plurality of word lines WL and the plurality of bit lines BL may not necessarily extend in one direction as in the memory cell array 5 illustrated in FIG. 12, for example.

### 3. Example

Hereinafter, description is given of specific Example of the present disclosure.

First, an experiment was performed to confirm the effects of the barrier layer for the working of a memory device. As a film prior to the working, a stacked film was prepared in which a lower electrode layer, a resistance change layer, an ion source layer, a barrier layer, and an upper electrode layer were stacked in this order. For the purpose of comparison, a stacked film was prepared in which the barrier layer was removed from the above configuration. The lower electrode layer was formed using titanium nitride (TiN). The resistance change layer was a stacked film of a 1 nm aluminum oxide (Al₂O₃) film and a 3.5 nm layer of aluminum (Al), tellurium (Te), and nitrogen (N). The ion source layer was formed from TeAlCuZr. The upper electrode layer was formed using tungsten (W).

Known examples of the barrier layer include titanium nitride (TiN), tantalum (Ta), and the like, as common barrier metals. However, as a result of a consideration, it was appreciated that the use thereof decreased the adhesiveness between the ion source layer and the barrier layer, resulting in detachment. Therefore, a study was conducted on the barrier layer that allows for sufficient adhesiveness.

### Experiments

Samples 1 to 91 were prepared in which respective composition ratios of the ion source layer and the barrier layer were changed, a thickness of the ion source layer was changed between 10 nm and 20 nm, and a thickness of the barrier layer was changed between 2 nm and 12 nm to confirm the adhesiveness between the ion source layer and the barrier layer. It is to be noted that the total thickness of the ion source layer and the barrier layer was set to 15 nm to 25 nm. The thickness of tungsten (W), which is the upper electrode layer, was set to 40 nm. In order not to complicate the working condition, an element other than copper (Cu) used for the ion source layer was selected for the barrier layer. The composition ratio of copper (Cu) in the ion source layer is set to a range from 4 atomic percent to 19 atomic percent. Tables 1A to 1C exhibit compositions and thicknesses of the ion source layer and the barrier layer of samples 1 to 91.

TABLE 1A

| | Ion Source Layer | | | | | Barrier Layer | | | |
|---|---|---|---|---|---|---|---|---|---|
| | Composition Ratio | | | | | Composition Ratio | | | |
| Sample | (Atomic %) | | | | | (Atomic %) | | | |
| No. | Te | Al | Zr | Cu | Thickness | Te | Al | Zr | Thickness |
| 1 | 38.0 | 38.0 | 11.0 | 13.0 | 15.0 | 0.0 | 0.0 | 0.0 | 0.0 |
| 2 | 38.0 | 38.0 | 11.0 | 13.0 | 15.0 | 0.0 | 65.0 | 35.0 | 7.0 |
| 3 | 38.0 | 38.0 | 11.0 | 13.0 | 15.0 | 0.0 | 58.2 | 41.8 | 8.0 |
| 4 | 38.0 | 38.0 | 11.0 | 13.0 | 15.0 | 0.0 | 58.2 | 41.8 | 2.0 |
| 5 | 38.0 | 38.0 | 11.0 | 13.0 | 15.0 | 0.0 | 58.2 | 41.8 | 6.0 |
| 6 | 38.0 | 38.0 | 11.0 | 13.0 | 15.0 | 0.0 | 51.1 | 48.9 | 7.0 |
| 7 | 38.0 | 38.0 | 11.0 | 13.0 | 15.0 | 0.0 | 41.1 | 58.9 | 6.0 |
| 8 | 38.0 | 38.0 | 11.0 | 13.0 | 15.0 | 0.0 | 41.1 | 58.9 | 6.0 |
| 9 | 38.0 | 38.0 | 11.0 | 13.0 | 15.0 | 0.0 | 0.0 | 100.0 | 2.0 |
| 10 | 38.0 | 38.0 | 11.0 | 13.0 | 15.0 | 0.0 | 0.0 | 100.0 | 2.0 |
| 11 | 35.0 | 43.0 | 10.0 | 12.0 | 15.0 | 0.0 | 0.0 | 100.0 | 2.0 |
| 12 | 46.0 | 26.0 | 13.0 | 15.0 | 15.0 | 0.0 | 0.0 | 100.0 | 2.0 |
| 13 | 56.0 | 16.0 | 13.0 | 15.0 | 15.0 | 0.0 | 0.0 | 100.0 | 2.0 |
| 14 | 63.0 | 9.0 | 13.0 | 15.0 | 15.0 | 0.0 | 0.0 | 100.0 | 2.0 |
| 15 | 45.8 | 15.5 | 17.8 | 20.9 | 15.0 | 0.0 | 0.0 | 100.0 | 2.0 |
| 16 | 30.6 | 40.5 | 13.3 | 15.6 | 15.0 | 0.0 | 0.0 | 100.0 | 2.0 |
| 17 | 38.0 | 38.0 | 11.0 | 13.0 | 15.0 | 0.0 | 0.0 | 100.0 | 2.0 |
| 18 | 38.0 | 38.0 | 11.0 | 13.0 | 15.0 | 0.0 | 0.0 | 100.0 | 2.0 |
| 19 | 38.0 | 38.0 | 11.0 | 13.0 | 15.0 | 0.0 | 0.0 | 100.0 | 2.0 |
| 20 | 35.0 | 43.0 | 10.0 | 12.0 | 15.0 | 0.0 | 0.0 | 100.0 | 2.0 |
| 21 | 38.0 | 38.0 | 11.0 | 13.0 | 15.0 | 0.0 | 0.0 | 100.0 | 2.0 |
| 22 | 38.0 | 38.0 | 11.0 | 13.0 | 15.0 | 0.0 | 0.0 | 100.0 | 2.0 |
| 23 | 38.0 | 38.0 | 11.0 | 13.0 | 15.0 | 0.0 | 0.0 | 100.0 | 2.0 |
| 24 | 38.0 | 38.0 | 11.0 | 13.0 | 20.0 | 0.0 | 0.0 | 100.0 | 2.0 |
| 25 | 38.0 | 38.0 | 11.0 | 13.0 | 15.0 | 15.7 | 15.7 | 68.5 | 6.0 |
| 26 | 43.0 | 44.0 | 6.0 | 7.0 | 15.0 | 15.7 | 15.7 | 68.5 | 6.0 |
| 27 | 46.0 | 47.0 | 3.0 | 4.0 | 15.0 | 15.7 | 15.7 | 68.5 | 6.0 |
| 28 | 41.5 | 41.5 | 7.8 | 9.2 | 15.0 | 15.7 | 15.7 | 68.5 | 6.0 |
| 29 | 40.0 | 40.0 | 6.0 | 14.0 | 16.0 | 15.7 | 15.7 | 68.5 | 6.0 |
| 30 | 36.0 | 35.0 | 10.0 | 19.0 | 16.0 | 17.2 | 17.2 | 65.6 | 5.5 |

TABLE 1B

| | Ion Source Layer | | | | | Barrier Layer | | | |
|---|---|---|---|---|---|---|---|---|---|
| | Composition Ratio | | | | | Composition Ratio | | | |
| Sample | (Atomic %) | | | | | (Atomic %) | | | |
| No. | Te | Al | Zr | Cu | Thickness | Te | Al | Zr | Thickness |
| 31 | 38.0 | 38.0 | 11.0 | 13.0 | 15.0 | 18.4 | 38.1 | 43.4 | 9.0 |
| 32 | 38.0 | 38.0 | 11.0 | 13.0 | 15.0 | 19.0 | 19.0 | 62.0 | 5.0 |
| 33 | 38.0 | 38.0 | 11.0 | 13.0 | 15.0 | 20.4 | 20.4 | 59.2 | 7.0 |
| 34 | 38.0 | 38.0 | 11.0 | 13.0 | 15.0 | 21.2 | 21.2 | 57.7 | 4.5 |
| 35 | 38.0 | 38.0 | 11.0 | 13.0 | 15.0 | 21.7 | 27.1 | 51.2 | 8.0 |
| 36 | 38.0 | 38.0 | 11.0 | 13.0 | 15.0 | 23.9 | 23.9 | 52.1 | 4.0 |
| 37 | 38.0 | 38.0 | 11.0 | 13.0 | 15.0 | 23.9 | 23.9 | 52.1 | 6.0 |
| 38 | 36.0 | 35.0 | 10.0 | 19.0 | 16.0 | 23.9 | 23.9 | 52.1 | 6.0 |
| 39 | 38.0 | 38.0 | 11.0 | 13.0 | 15.0 | 25.5 | 0.0 | 74.5 | 6.0 |
| 40 | 36.0 | 35.0 | 10.0 | 19.0 | 16.0 | 26.4 | 11.3 | 62.3 | 7.0 |
| 41 | 43.0 | 44.0 | 6.0 | 7.0 | 15.0 | 26.4 | 11.3 | 62.3 | 7.0 |
| 42 | 46.0 | 47.0 | 3.0 | 4.0 | 15.0 | 26.4 | 11.3 | 62.3 | 7.0 |
| 43 | 41.5 | 41.5 | 7.8 | 9.2 | 15.0 | 26.4 | 11.3 | 62.3 | 7.0 |
| 44 | 40.0 | 40.0 | 6.0 | 14.0 | 16.0 | 26.4 | 11.3 | 62.3 | 7.0 |
| 45 | 38.0 | 38.0 | 11.0 | 13.0 | 15.0 | 26.5 | 26.5 | 47.0 | 7.0 |
| 46 | 38.0 | 38.0 | 11.0 | 13.0 | 10.0 | 26.6 | 39.9 | 33.5 | 11.2 |
| 47 | 38.0 | 38.0 | 11.0 | 13.0 | 15.0 | 29.0 | 29.0 | 42.1 | 5.0 |
| 48 | 38.0 | 38.0 | 11.0 | 13.0 | 10.0 | 29.1 | 29.1 | 41.7 | 12.0 |
| 49 | 38.0 | 38.0 | 11.0 | 13.0 | 10.0 | 30.7 | 48.0 | 21.3 | 9.5 |
| 50 | 41.5 | 41.5 | 7.8 | 9.2 | 10.0 | 31.2 | 48.8 | 20.0 | 9.3 |
| 51 | 37.0 | 46.0 | 8.0 | 9.0 | 10.0 | 31.2 | 48.8 | 20.0 | 9.3 |
| 52 | 32.0 | 46.0 | 10.0 | 12.0 | 10.0 | 31.2 | 48.8 | 20.0 | 9.3 |
| 53 | 45.6 | 37.5 | 7.8 | 9.1 | 10.0 | 31.2 | 48.8 | 20.0 | 9.3 |
| 54 | 38.0 | 38.0 | 11.0 | 13.0 | 10.0 | 31.2 | 48.8 | 20.0 | 9.3 |
| 55 | 38.0 | 38.0 | 11.0 | 13.0 | 15.0 | 31.3 | 13.4 | 55.3 | 6.0 |
| 56 | 36.0 | 35.0 | 10.0 | 19.0 | 16.0 | 31.3 | 13.4 | 55.3 | 6.0 |
| 57 | 38.0 | 38.0 | 11.0 | 13.0 | 10.0 | 31.7 | 49.6 | 18.7 | 9.2 |
| 58 | 38.0 | 38.0 | 11.0 | 13.0 | 10.0 | 32.4 | 32.4 | 35.1 | 11.2 |
| 59 | 38.0 | 38.0 | 11.0 | 13.0 | 10.0 | 32.4 | 32.4 | 35.1 | 11.2 |
| 60 | 38.0 | 38.0 | 11.0 | 13.0 | 10.0 | 32.4 | 32.4 | 35.1 | 11.2 |

TABLE 1C

| | Ion Source Layer | | | | | Barrier Layer | | | |
|---|---|---|---|---|---|---|---|---|---|
| | Composition Ratio | | | | | Composition Ratio | | | |
| Sample | (Atomic %) | | | | | (Atomic %) | | | |
| No. | Te | Al | Zr | Cu | Thickness | Te | Al | Zr | Thickness |
| 61 | 38.0 | 38.0 | 11.0 | 13.0 | 13.0 | 32.4 | 32.4 | 35.1 | 11.2 |
| 62 | 33.0 | 49.0 | 8.0 | 10.0 | 10.0 | 32.4 | 32.4 | 35.1 | 11.2 |
| 63 | 28.8 | 47.5 | 10.9 | 12.8 | 10.0 | 32.4 | 32.4 | 35.1 | 11.2 |
| 64 | 38.0 | 38.0 | 11.0 | 13.0 | 15.0 | 33.9 | 0.0 | 66.1 | 7.0 |
| 65 | 43.0 | 44.0 | 6.0 | 7.0 | 15.0 | 33.9 | 0.0 | 66.1 | 7.0 |
| 66 | 41.5 | 41.5 | 7.8 | 9.2 | 15.0 | 33.9 | 0.0 | 66.1 | 7.0 |
| 67 | 35.0 | 43.0 | 10.0 | 12.0 | 15.0 | 33.9 | 0.0 | 66.1 | 7.0 |
| 68 | 46.0 | 26.0 | 13.0 | 15.0 | 15.0 | 33.9 | 0.0 | 66.1 | 7.0 |
| 69 | 43.0 | 44.0 | 6.0 | 7.0 | 15.0 | 33.9 | 0.0 | 66.1 | 7.0 |
| 70 | 43.0 | 44.0 | 6.0 | 7.0 | 15.0 | 33.9 | 0.0 | 66.1 | 7.0 |
| 71 | 38.0 | 38.0 | 11.0 | 13.0 | 15.0 | 35.2 | 15.1 | 49.8 | 9.0 |
| 72 | 41.5 | 41.5 | 7.8 | 9.2 | 15.0 | 35.2 | 15.1 | 49.8 | 9.0 |
| 73 | 38.0 | 38.0 | 11.0 | 13.0 | 10.0 | 35.8 | 35.9 | 28.3 | 10.2 |
| 74 | 38.0 | 38.0 | 11.0 | 13.0 | 10.0 | 36.6 | 24.4 | 39.0 | 11.6 |
| 75 | 38.0 | 38.0 | 11.0 | 13.0 | 10.0 | 37.1 | 37.1 | 25.7 | 9.8 |
| 76 | 38.0 | 38.0 | 11.0 | 13.0 | 10.0 | 38.0 | 25.3 | 36.6 | 11.2 |
| 77 | 38.0 | 38.0 | 11.0 | 13.0 | 10.0 | 38.7 | 38.7 | 22.6 | 9.5 |
| 78 | 38.0 | 38.0 | 11.0 | 13.0 | 10.0 | 39.3 | 39.4 | 21.3 | 9.3 |
| 79 | 38.0 | 38.0 | 11.0 | 13.0 | 10.0 | 40.0 | 40.1 | 19.9 | 9.2 |
| 80 | 38.0 | 38.0 | 11.0 | 13.0 | 10.0 | 40.0 | 40.1 | 19.9 | 9.2 |
| 81 | 38.0 | 38.0 | 11.0 | 13.0 | 15.0 | 40.6 | 0.0 | 59.4 | 6.0 |
| 82 | 43.0 | 44.0 | 6.0 | 7.0 | 15.0 | 40.6 | 0.0 | 59.4 | 6.0 |
| 83 | 41.5 | 41.5 | 7.8 | 9.2 | 15.0 | 40.6 | 0.0 | 59.4 | 6.0 |
| 84 | 38.0 | 38.0 | 11.0 | 13.0 | 15.0 | 40.6 | 0.0 | 59.4 | 6.0 |
| 85 | 43.0 | 44.0 | 6.0 | 7.0 | 15.0 | 40.6 | 0.0 | 59.4 | 6.0 |
| 86 | 38.0 | 38.0 | 11.0 | 13.0 | 10.0 | 40.6 | 0.0 | 59.4 | 12.0 |
| 87 | 38.0 | 38.0 | 11.0 | 13.0 | 10.0 | 40.6 | 0.0 | 59.4 | 12.0 |
| 88 | 38.0 | 38.0 | 11.0 | 13.0 | 10.0 | 40.6 | 0.0 | 59.4 | 12.0 |
| 89 | 38.0 | 38.0 | 11.0 | 13.0 | 15.0 | 40.6 | 0.0 | 59.4 | 8.0 |
| 90 | 38.0 | 38.0 | 11.0 | 13.0 | 10.0 | 43.3 | 18.6 | 38.1 | 11.2 |
| 91 | 41.5 | 41.5 | 7.8 | 9.2 | 15.0 | 50.7 | 0.0 | 49.3 | 5.0 |

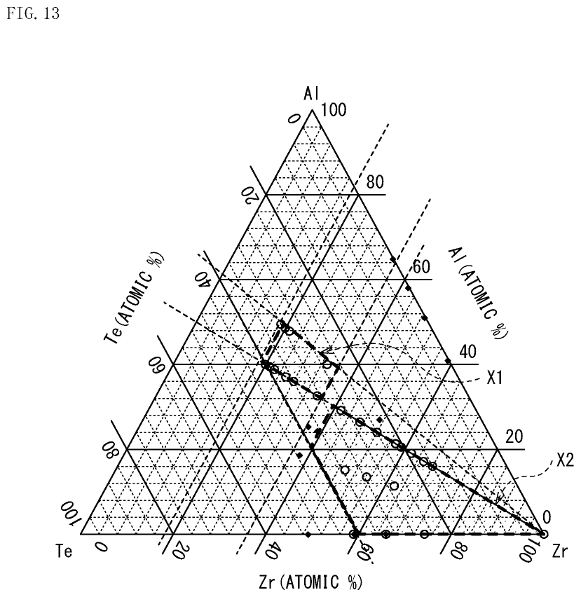

Table 2 summarizes results of confirmation of the adhesiveness between the ion source layer and the barrier layer of Sample 1 to Sample 91. In Table 2, A indicates a case where the adhesiveness is favorable, and B indicates a case where the adhesiveness is unfavorable. FIG. 13 is a composition map (a ternary diagram of Al, Zr, and Te) representing a compositional range of aluminum (Al), zirconium (Zr), and tellurium (Te) included in the barrier layer. In FIG. 13, those having favorable adhesiveness were each plotted as a white circle (o), and those having unfavorable adhesiveness are each plotted as a black diamond (♦).

TABLE 2

| Sample | |
|---|---|
| No. | Adhesiveness |
| 1 | B |
| 2 | B |
| 3 | B |
| 4 | B |
| 5 | B |
| 6 | B |
| 7 | B |
| 8 | B |
| 9 | A |
| 10 | A |
| 11 | A |
| 12 | B |
| 13 | B |
| 14 | B |
| 15 | B |
| 16 | A |
| 17 | A |
| 18 | A |
| 19 | A |
| 20 | A |
| 21 | A |
| 22 | A |
| 23 | A |
| 24 | A |
| 25 | A |
| 26 | A |
| 27 | A |
| 28 | A |
| 29 | A |
| 30 | A |
| 31 | B |
| 32 | A |
| 33 | A |
| 34 | A |
| 35 | B |
| 36 | A |
| 37 | A |
| 38 | A |
| 39 | A |
| 40 | A |
| 41 | A |
| 42 | A |
| 43 | A |
| 44 | A |
| 45 | A |
| 46 | A |
| 47 | A |
| 48 | A |
| 49 | A |
| 50 | A |
| 51 | A |
| 52 | A |
| 53 | A |
| 54 | A |
| 55 | A |
| 56 | A |
| 57 | A |
| 58 | A |
| 59 | A |
| 60 | A |
| 61 | A |
| 62 | A |
| 63 | A |
| 64 | A |
| 65 | A |
| 66 | A |
| 67 | A |
| 68 | B |
| 69 | A |
| 70 | A |
| 71 | A |
| 72 | A |
| 73 | A |
| 74 | B |
| 75 | B |
| 76 | B |
| 77 | A |
| 78 | A |
| 79 | A |
| 80 | A |
| 81 | B |
| 82 | B |
| 83 | B |
| 84 | B |
| 85 | B |
| 86 | A |
| 87 | A |
| 88 | A |
| 89 | B |
| 90 | B |
| 91 | B |

It is appreciated, from FIG. 13, that the composition region of the barrier layer that is able to secure the adhesiveness is divided into two regions (a region X1 and a region X2). In the region X1, the zirconium (Zr) concentration is 18.5 atomic percent or more and 36 atomic percent or less, and the concentration ratio (Te/Al) between tellurium (Te) and aluminum (Al) is 0.64 or more and 1.0 or less. In the region X2, the zirconium (Zr) concentration is 40 atomic percent or more, the concentration ratio (Te/Al) between tellurium (Te) and aluminum (Al) is 1.0 or more, and the tellurium (Te) concentration is less than 40 atomic percent.

However, in a condition of Al=0 of the region X2, there are points where the favorable one (o) and unfavorable one (♦) overlap. This means that there is a case where favorableness or unfavorableness of the adhesiveness is not determined only by the composition of the barrier layer.

Tables 3A and 3B extract the condition of Al=0 of the region X2. In Tables 3A and 3B, A indicates a case where the adhesiveness was favorable, and B indicates a case where the adhesiveness was unfavorable. In addition, A indicates those conforming to each determination standard, and B indicates those not conforming thereto. Each adhesiveness is influenced by, in addition to the composition of the barrier layer, the compositions of the barrier layer and the ion source layer as well as the average composition including each thickness of the barrier layer and the ion source layer. Specifically, the barrier layer includes zirconium (Zr; zirconium (Zr) concentration of 100 atomic percent), and the tellurium (Te) concentration is less than 42.5 atomic percent, among the three elements of tellurium (Te), aluminum (Al), and zirconium (Zr) excluding copper (Cu) in the average composition ratio of the ion source layer and the barrier layer; alternatively, the barrier layer includes zirconium (Zr) and tellurium (Te), and the zirconium (Zr) concentration is 59.4 atomic percent or more and less than 100 atomic percent and the tellurium (Te) concentration is less than 42.5 atomic percent, among the three elements of tellurium (Te), aluminum (Al), and zirconium (Zr) excluding copper (Cu) in the average composition ratio of the ion source layer and the barrier layer. It is appreciated that the actual adhesiveness becomes favorable when the above conditions are satisfied.

TABLE 3A

| | | | | | | | | | Determination | |
|---|---|---|---|---|---|---|---|---|---|---|
| | | | | | | | | | Standard | |
| | | | | | | | | | | Ion |
| | Barrier Layer | | | | Ion Source Layer + | | | | | Source |
| | | | | | Barrier Layer | | | | | Layer + |
| | Composition | | | | Composition | | | | Barrier | Barrier |
| | Ratio | | | | Ratio | | | | Layer | Layer |
| Sample | (Atomic %) | | | Thickness | (Atomic %) | | | | Zr ≤ | Te < |
| No. | Te | Al | Zr | (nm) | Te | Al | Zr | Adhesiveness | 59.4% | 42.5% |
| 9 | 0.0 | 0.0 | 100.0 | 2.0 | 37.9 | 37.8 | 24.3 | A | A | A |
| 10 | 0.0 | 0.0 | 100.0 | 2.0 | 37.9 | 37.8 | 24.3 | A | A | A |
| 11 | 0.0 | 0.0 | 100.0 | 2.0 | 34.6 | 42.5 | 22.8 | A | A | A |
| 12 | 0.0 | 0.0 | 100.0 | 2.0 | 46.4 | 26.2 | 27.4 | B | A | B |
| 13 | 0.0 | 0.0 | 100.0 | 2.0 | 55.9 | 16.0 | 28.1 | B | A | B |
| 14 | 0.0 | 0.0 | 100.0 | 2.0 | 62.5 | 8.9 | 28.6 | B | A | B |
| 15 | 0.0 | 0.0 | 100.0 | 2.0 | 49.1 | 16.6 | 34.4 | B | A | B |
| 16 | 0.0 | 0.0 | 100.0 | 2.0 | 31.5 | 41.7 | 26.8 | A | A | A |
| 17 | 0.0 | 0.0 | 100.0 | 2.0 | 37.9 | 37.8 | 24.3 | A | A | A |
| 18 | 0.0 | 0.0 | 100.0 | 2.0 | 37.9 | 37.8 | 24.3 | A | A | A |
| 19 | 0.0 | 0.0 | 100.0 | 2.0 | 37.9 | 37.8 | 24.3 | A | A | A |
| 20 | 0.0 | 0.0 | 100.0 | 2.0 | 34.6 | 42.5 | 22.8 | A | A | A |
| 21 | 0.0 | 0.0 | 100.0 | 2.0 | 37.9 | 37.8 | 24.3 | A | A | A |
| 22 | 0.0 | 0.0 | 100.0 | 2.0 | 37.9 | 37.8 | 24.3 | A | A | A |
| 23 | 0.0 | 0.0 | 100.0 | 2.0 | 35.5 | 35.5 | 29.0 | A | A | A |
| 24 | 0.0 | 0.0 | 100.0 | 2.0 | 39.2 | 39.1 | 21.7 | A | A | A |

TABLE 3B

| | | | | | | | | | Determination | |
|---|---|---|---|---|---|---|---|---|---|---|
| | | | | | | | | | Standard | |
| | | | | | | | | | | Ion |
| | Barrier Layer | | | | Ion Source Layer + | | | | | Source |
| | | | | | Barrier Layer | | | | | Layer + |
| | Composition | | | | Composition | | | | Barrier | Barrier |
| | Ratio | | | | Ratio | | | | Layer | Layer |
| Sample | (Atomic %) | | | Thickness | (Atomic %) | | | | Zr ≤ | Te < |
| No. | Te | Al | Zr | (nm) | Te | Al | Zr | Adhesiveness | 59.4% | 42.5% |
| 64 | 33.9 | 0.0 | 66.1 | 7.0 | 40.6 | 29.8 | 29.6 | A | A | A |
| 65 | 33.9 | 0.0 | 66.1 | 7.0 | 42.4 | 32.6 | 25.0 | A | A | A |
| 66 | 33.9 | 0.0 | 66.1 | 7.0 | 42.0 | 31.4 | 26.6 | A | A | A |
| 67 | 33.9 | 0.0 | 66.1 | 7.0 | 38.0 | 33.7 | 28.3 | A | A | A |
| 68 | 33.9 | 0.0 | 66.1 | 7.0 | 47.3 | 20.3 | 32.4 | B | A | B |
| 69 | 33.9 | 0.0 | 66.1 | 7.0 | 42.4 | 32.6 | 25.0 | A | A | A |
| 70 | 33.9 | 0.0 | 66.1 | 7.0 | 42.4 | 32.6 | 25.0 | A | A | A |
| 81 | 40.6 | 0.0 | 59.4 | 6.0 | 42.8 | 31.4 | 25.7 | B | A | B |
| 82 | 40.6 | 0.0 | 59.4 | 6.0 | 44.7 | 34.4 | 20.9 | B | A | B |
| 83 | 40.6 | 0.0 | 59.4 | 6.0 | 44.3 | 33.1 | 22.6 | B | A | B |
| 84 | 40.6 | 0.0 | 59.4 | 6.0 | 42.8 | 31.4 | 25.7 | B | A | B |
| 85 | 40.6 | 0.0 | 59.4 | 6.0 | 44.7 | 34.4 | 20.9 | B | A | B |
| 86 | 40.6 | 0.0 | 59.4 | 12.0 | 42.0 | 20.2 | 37.8 | A | A | A |
| 87 | 40.6 | 0.0 | 59.4 | 12.0 | 42.0 | 20.2 | 37.8 | A | A | A |
| 88 | 40.6 | 0.0 | 59.4 | 12.0 | 42.0 | 20.2 | 37.8 | A | A | A |
| 89 | 40.6 | 0.0 | 59.4 | 8.0 | 42.6 | 28.8 | 28.6 | B | A | B |

When dry etching working was performed after going through lithography for a stacked film with sufficient adhesiveness secured, it was able to be confirmed that the workability was improved as compared with a stacked film without the barrier layer. It is presumed that the barrier layer suppresses the diffusion of copper (Cu) from the ion source layer to the upper electrode layer, thus improving the etching rate of the upper electrode layer.

From those described above, it has been appreciated that providing the barrier layer including zirconium (Zr) at a higher concentration than the ion source layer between the ion source layer and the upper electrode makes it possible to secure the workability of stacked films included in the memory device as well as the adhesiveness between the ion source layer and the upper electrode, and further that providing the barrier layer that satisfies any of the following four conditions makes it possible to stably secure the workability of the stacked films included in the memory device as well as the adhesiveness between the ion source layer and the upper electrode. Among the four conditions, the first condition is that the zirconium (Zr) concentration is 18.5 atomic percent or more and 36 atoms, and the concentration ratio (Te/Al) between tellurium (Te) and aluminum (Al) is 0.64 or more and 1.0 or less. The second condition is that the zirconium (Zr) concentration is 40 atomic percent or more, the concentration ratio (Te/Al) between tellurium (Te) and aluminum (Al) is 1.0 or more, and the tellurium (Te) concentration is less than 40 atomic percent. The third condition is that the barrier layer includes zirconium (Zr; zirconium (Zr) concentration is 100 atomic percent), and the tellurium (Te) concentration is less than 42.5 atomic percent among the three elements of tellurium (Te), aluminum (Al), and zirconium (Zr) excluding copper (Cu) in the average composition ratio of the ion source layer and the barrier layer. The fourth condition is that the barrier layer includes zirconium (Zr) and tellurium (Te), the zirconium (Zr) concentration is 59.4 atomic percent or more and less than 100 atomic percent, and the tellurium (Te) concentration is less than 42.5 atomic percent among the three elements of tellurium (Te), aluminum (Al), and zirconium (Zr) excluding copper (Cu) in the average composition ratio of the ion source layer and the barrier layer.

Although the description has been given hereinabove with reference to the embodiment, the modification example, and Example, the contents of the present disclosure are not limited to the foregoing embodiment and the like, and the configurations of the memory device and the memory cell array of the present disclosure may be freely modified as long as effects similar to those of the foregoing embodiment and the like are achieved.

For example, the ion source layer 24 is not limited to a single layer structure, and may be a stack of a plurality of compositions. In addition, each layer may not be an alloy including all necessary elements, and a stacked structure, in which thin layers of an alloy including a plurality of elements or respective elements are stacked, may be adopted as long as the average compositions in the layer are the same.

It is to be noted that the effects described herein are not necessarily limitative, and may be any of the effects described in the present disclosure.

It is to be noted that the present disclosure may also have the following configurations. According to the following configurations, there is provided, between the storage layer and the second electrode, the barrier layer that includes zirconium at a high concentration than at least the storage layer and that has a copper concentration, at the interface with the second electrode, being lower than that of the storage layer. This makes it possible to improve the adhesiveness of the second electrode to the lower layer while suppressing the diffusion of copper (Cu) from the storage layer to the second electrode. Hence, it is possible to provide the memory cell array having high density and large capacity.

(1)

A storage device including:

a first electrode;

a second electrode;

a storage layer provided between the first electrode and the second electrode and including at least copper, aluminum, zirconium, and tellurium; and

a barrier layer provided between the storage layer and the second electrode and including zirconium at a higher concentration than at least the storage layer, the barrier layer having a copper concentration, at an interface with the second electrode, being lower than the storage layer.

(2)

The storage device according to (1), in which

the barrier layer has a zirconium concentration of 100 atomic percent, and

a tellurium concentration is less than 42.5 atomic percent among three elements of tellurium, aluminum, and zirconium in an average composition ratio of the storage layer and the barrier layer.

(3)

The storage device according to (1), in which

the barrier layer further includes tellurium, and has a zirconium concentration of 59.4 atomic percent or more and less than 100 atomic percent, and

a tellurium concentration is less than 42.5 atomic percent among three elements of tellurium, aluminum, and zirconium in an average composition ratio of the storage layer and the barrier layer.

(4)

The storage device according to (1), in which the barrier layer further includes tellurium and aluminum, and has a zirconium concentration of 40 atomic percent or more, a concentration ratio between tellurium and aluminum of 1.0 or more, and a tellurium concentration of less than 40 atomic percent.

(5)

The storage device according to (1), in which the barrier layer further includes tellurium and aluminum, and has a zirconium concentration of 18.5 atomic percent or more and 36 atomic percent or less, and a concentration ratio between tellurium and aluminum of 0.64 or more and 1.0 or less.

(6)

The storage device according to any one of (1) to (5), in which a thickness of the barrier layer in a stacking direction is 2 nm or more and 12 nm or less.

(7)

The storage device according to any one of (1) to (6), in which a total thickness of the storage layer and the barrier layer in the stacking direction is 15 nm or more and 25 nm or less.

(8)

The storage device according to any one of (1) to (7), in which

the storage layer includes a resistance change layer and an ion source layer stacked in order from side of the first electrode,

the resistance change layer switches a resistance state at a predetermined voltage or more by applying a voltage between the first electrode and the second electrode, and

the ion source layer includes at least copper, aluminum, zirconium, and tellurium.

(9)

The storage device according to (8), in which

the resistance change layer has a single layer structure including a first layer that includes tellurium and nitrogen, or a stacked structure of the first layer and a second layer including an oxide that includes aluminum, and

the first layer is directly stacked on the ion source layer.

(10)

The storage device according to any one of (1) to (9), in which the second electrode is formed to include tungsten.

(11)

A storage unit including:

one or a plurality of first wiring lines extending in one direction;

one or a plurality of second wiring lines extending in another direction and intersecting the first wiring line; and

one or a plurality of storage devices disposed at an intersection of the first wiring line and the second wiring line,

the storage device including
a first electrode,
a second electrode including tungsten,
a storage layer provided between the first electrode and the second electrode and including at least copper, aluminum, zirconium, and tellurium, and
a barrier layer provided between the storage layer and the second electrode and including zirconium at a higher concentration than at least the storage layer, the barrier layer having a copper concentration, at an interface with the second electrode, being lower than the storage layer.
   (12)

The storage unit according to (11), in which one of the first wiring line and the second wiring line serves also as the second electrode of the storage device.

(13)

The storage unit according to (11) or (12), further including, at the intersection of the first wiring line and the second wiring line, a switch device that changes into a low-resistance state by setting an applied voltage to a predetermined threshold voltage or more, and changes into a high-resistance state by lowering the applied voltage to less than the threshold voltage, without going through a phase change between an amorphous phase and a crystalline phase.

(14)

The storage unit according to (13), in which the switch device is stacked on the storage device.

(15)

The storage unit according to (13) or (14), in which the switch device includes a third electrode, a switch layer including at least one type of a chalcogen element selected from tellurium, selenium, and sulfur, and a fourth electrode, which are stacked in this order.

(16)

The storage unit according to (15), in which one of the first wiring line and the second wiring line serves also as the third electrode of the switch device.

(17)

The storage unit according to (15) or (16), in which the first electrode of the storage device serves also as the fourth electrode of the switch device.

This application claims the benefit of Japanese Priority Patent Application JP2019-170594 filed with the Japan Patent Office on Sep. 19, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A storage device, comprising:
a first electrode;
a second electrode;
a storage layer provided between the first electrode and the second electrode and including at least copper, aluminum, zirconium, and tellurium; and
a barrier layer provided between the storage layer and the second electrode and including zirconium at a higher concentration than at least the storage layer, the barrier layer having a copper concentration, at an interface with the second electrode, being lower than the storage layer.

2. The storage device according to claim 1, wherein
the barrier layer has a zirconium concentration of 100 atomic percent, and
a tellurium concentration is less than 42.5 atomic percent among three elements of tellurium, aluminum, and zirconium in an average composition ratio of the storage layer and the barrier layer.

3. The storage device according to claim 1, wherein
the barrier layer further includes tellurium, and has a zirconium concentration of 59.4 atomic percent or more and less than 100 atomic percent, and
a tellurium concentration is less than 42.5 atomic percent among three elements of tellurium, aluminum, and zirconium in an average composition ratio of the storage layer and the barrier layer.

4. The storage device according to claim 1, wherein the barrier layer further includes tellurium and aluminum, and has a zirconium concentration of 40 atomic percent or more, a concentration ratio between tellurium and aluminum of 1.0 or more, and a tellurium concentration of less than 40 atomic percent.

5. The storage device according to claim 1, wherein the barrier layer further includes tellurium and aluminum, and has a zirconium concentration of 18.5 atomic percent or more and 36 atomic percent or less, and a concentration ratio between tellurium and aluminum of 0.64 or more and 1.0 or less.

6. The storage device according to claim 1, wherein a thickness of the barrier layer in a stacking direction is 2 nm or more and 12 nm or less.

7. The storage device according to claim 1, wherein a total thickness of the storage layer and the barrier layer in a stacking direction is 15 nm or more and 25 nm or less.

8. The storage device according to claim 1, wherein
the storage layer includes a resistance change layer and an ion source layer stacked in order from side of the first electrode,
the resistance change layer switches a resistance state at a predetermined voltage or more by applying a voltage between the first electrode and the second electrode, and
the ion source layer includes at least copper, aluminum, zirconium, and tellurium.

9. The storage device according to claim 8, wherein
the resistance change layer has a single layer structure including a first layer that includes tellurium and nitrogen, or a stacked structure of the first layer and a second layer including an oxide that includes aluminum, and
the first layer is directly stacked on the ion source layer.

10. The storage device according to claim 1, wherein the second electrode is formed to include tungsten.

11. A storage unit comprising:
one or a plurality of first wiring lines extending in one direction;
one or a plurality of second wiring lines extending in another direction and intersecting the first wiring line; and
one or a plurality of storage devices disposed at an intersection of the first wiring line and the second wiring line,
the storage device including
a first electrode,
a second electrode including tungsten,
a storage layer provided between the first electrode and the second electrode and including at least copper, aluminum, zirconium, and tellurium, and
a barrier layer provided between the storage layer and the second electrode and including zirconium at a higher concentration than at least the storage layer, the barrier layer having a copper concentration, at an interface with the second electrode, being lower than the storage layer.

12. The storage unit according to claim 11, wherein one of the first wiring line and the second wiring line serves also as the second electrode of the storage device.

13. The storage unit according to claim 11, further comprising, at the intersection of the first wiring line and the second wiring line, a switch device that changes into a low-resistance state by setting an applied voltage to a predetermined threshold voltage or more, and changes into a high-resistance state by lowering the applied voltage to less than the threshold voltage, without going through a phase change between an amorphous phase and a crystalline phase.

14. The storage unit according to claim 13, wherein the switch device is stacked on the storage device.

15. The storage unit according to claim 13, wherein the switch device includes a third electrode, a switch layer including at least one type of a chalcogen element selected from tellurium, selenium, and sulfur, and a fourth electrode, which are stacked in this order.

16. The storage unit according to claim 15, wherein one of the first wiring line and the second wiring line serves also as the third electrode of the switch device.

17. The storage unit according to claim 15, wherein the first electrode of the storage device serves also as the fourth electrode of the switch device.
